(19) United States
(12) Patent Application Publication
(10) Pub. No.: US 2008/0217759 A1
(43) Pub. Date: Sep. 11, 2008

(54) Chip package substrate and structure thereof

(75) Inventors: Chi Chih Lin, Pingjhen City (TW); Bo Sun, Pingjhen City (TW); Hung Jen Wang, Gueishan Township (TW)

Correspondence Address: ABELMAN, FRAYNE & SCHWAB, 666 THIRD AVENUE, 10TH FLOOR, NEW YORK, NY, 10017, US

(73) Assignee: Taiwan Solutions Systems Corp.

(21) Appl. No.: 11/715,146

(22) Filed: Mar. 6, 2007

(51) Int. Cl. H01L 23/48; H01L 23/52

(52) U.S. Cl. 257/693; 257/737; 257/E23.01

(57) ABSTRACT

A chip package substrate includes multiple pairs of connection pads. Both pads of a connection pad pair are separated from each other with a distance, which is smaller than the side length of a chip. An insulation layer is configured on the connection pads but exposes a portion of the surface of each of connection pads, and then a contact pad is configured on the exposed surface of each of connection pads. Thus, the connection pads are moved inwardly to under the chip carrier area to reduce the size of the chip package.

### FIELD OF THE INVENTION

This invention relates to a structure of a chip package substrate and, more especially, for the surface mounting technology, the connection pads are moved inward under the chip carrier area to reduce the package size dramatically.

### BACKGROUND OF THE RELATED ART

A chip package substrate provides the functions of carrying a chip and protecting the chip to avoid suffering from the physical destruction caused by an external force or chemical erosion in accessing, to assure the signal transmission, to avoid the signal delay and to provide the heat dissipative path. For the frequent flashing high efficient electronic product, the electronic product is getting smaller and thinner, such as the network/communication product (like the mobile phone, PHS, GPS), message product(like the PDA, portable IA, electronic book), consuming electronic product (like the electronic dictionary, palm electronic game machine, stock machine, card machine), chemical medical product and the vehicle electronic product. Therefore, the chip package technology moves on the light, thin, short and small way.

For the chip package technology, each die, cut away from a wafer, is disposed on a carrier via the wire bonding or flip chip bonding and so on, where the carrier may be a lead frame or a substrate. The chip includes a plurality of bonding pads on its active surface, and those bonding pads are bonded to the bonding pads on the carrier, called contact pads, to electrically connect an external electrical circuit. After that, a molding process is followed to seal the chip and the bonding wire to complete the structure of the chip package.

A carrier, like a lead frame, shown in FIG. 1, includes a trace pattern 110, formed on a metallic plate via a photolithography with photoresist, and a metallic surface layer 111, like a tin, a silver or a nickel-golden layer. A multiple laminated layer substrate, shown in FIG. 2, includes an internal layer 222, such as an insulation layer, a glass prepreg or a multilayer, trace patterns 210, formed on top and bottom metallic plates via a photolithography with photoresist, metallic surface layers 211, formed by a surface process with coating a tin, a silver or a nickel-golden layer, a protective layer 221 on between traces and conductive balls 220, like tin balls, on the bottom metallic surface layer 220. A chip package structure, shown in FIG. 3, uses the lead frame as the carrier. A die pad 330 is configured on the trace pattern 110, and an adhesive layer 333 and a chip 335 are stacked on the die pad 330 subsequently. A wire 332 electrically connects the chip 335 and the trace pattern 110 and is sealed up with a plastic molding material 334. The other face of the trace pattern 110 is exposed out of the plastic molding material 334 and coated a metallic layer 331 by a surface process, such as a tin, a silver or a nickel-golden layer. A chip package structure, shown in FIG. 4, uses the multiple laminated layer substrate as the carrier. An adhesive layer 433 is configured on the protective layer 221 and a chip 435 is stacked on the adhesive layer 433 subsequently. A wire 432 electrically connects the chip 435 and the top trace pattern 210 and is sealed up with a plastic molding material 434. For the top view of an abovementioned chip package, the trace pattern is out of the chip carrier area and separates from the chip carrier area for a distance, and the chip electrically connects the trace pattern via the bonding wires across the distance.

The conventional lead frame structure of the chip package, which utilizes the lead frame as the carrier and the bonding wire to electrically connect the chip, has advantages of low cost and good heat dissipation, and the multiple laminated layer substrate of the chip package has advantage of small size by arranging the tin ball array under the bottom face as the connection pads. However, the current electronic component is made smaller and more compact, so the conventional chip package, made of the lead frame or the multiple laminated layer substrates, meets the limitation of shrinking the chip size.

### SUMMARY OF THE INVENTION

It is an object of this invention to provide a chip package substrate, which moves the connection pads under the chip carrier area to reduce the size of the chip package dramatically to approach the chip scale.

It is another object of this invention to provide a chip package structure, which increases the amount of the chip packages via the current technology of the lead frame structure to reduce the fabrication cost.

For achieving the abovementioned objects, a chip package substrate comprises a plurality of connection pads, which are separated from each other with a distance and the distance is shorter than one side length of a chip carrier area, an insulation layer, which is configured on each connection pad and a part of a first surface of the connection pad is exposed out of the insulation layer, and a plurality of contact pads, which are configured at the insulation layer and cover the exposed part of the first surface of the connection pad.. Thus, the distance between the bonding pad of the chip and the contact pad is reduced so that the chip package shrinks.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic diagram of a lead frame substrate in a prior art;

FIG. 2 is a schematic diagram of a multiple laminated layer substrate in a prior art;

FIG. 3 is a schematic diagram of a chip package structure in a prior art, which utilizes a lead frame substrate shown in FIG. 1;

FIG. 4 is a schematic diagram of a chip package structure in a prior art, which utilizes a multiple laminated layer substrate shown in FIG. 2;

FIG. 5A and FIG. 5B are cross-section view schematic diagrams of the chip carriers according to this invention;

FIG. 6A and FIG. 6B are cross-section view schematic diagrams of the chip carriers according to this invention;

FIG. 7A and FIG. 7B are schematic diagrams of the chip carriers with die pads according to this invention;

FIG. 8A and FIG. 8B are schematic diagrams of the chip carriers with die pads according to this invention;

FIG. 9 is a schematic diagram of a chip package structure according to this invention, which utilizes a chip package substrate shown in FIG. 6A as the carrier;

FIG. 10 is a schematic diagram of a CMOS sensor chip package structure according to this invention, which utilizes a chip package substrate shown in FIG. 6A as the carrier;

FIG. 11 is a schematic diagram of a pressure sensor chip package structure according to this invention, which utilizes a chip package substrate shown in FIG. 6A as the carrier;

FIG. 12 is a schematic diagram of a chip package structure according to this invention, which utilizes a chip package substrate shown in FIG. 6B as the carrier and the conductive balls as the conductive components, and the rear face of the chip is covered;

FIG. 13 is a schematic diagram of a chip package structure according to this invention, which utilizes a chip package substrate shown in FIG. 6B as the carrier and the conductive balls as the conductive components, and the rear face of the chip is exposed;

FIG. 14 is a schematic diagram of a chip package structure according to this invention, which utilizes a chip package substrate shown in FIG. 6B as the carrier and the bumps as the conductive components, and the rear face of the chip is covered; and

FIG. 15A and FIG. 15B are the diagrams showing the top views of the chip package substrates according to this invention.

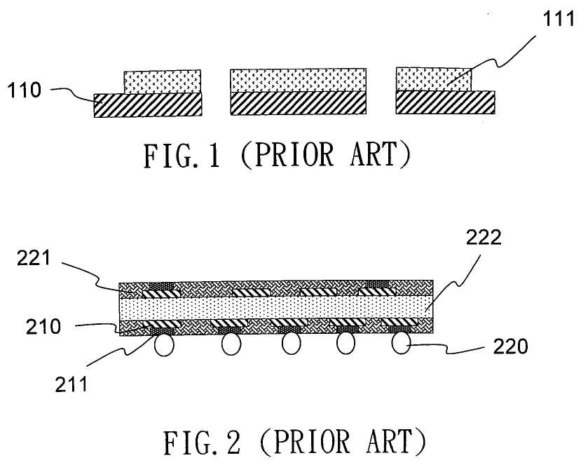

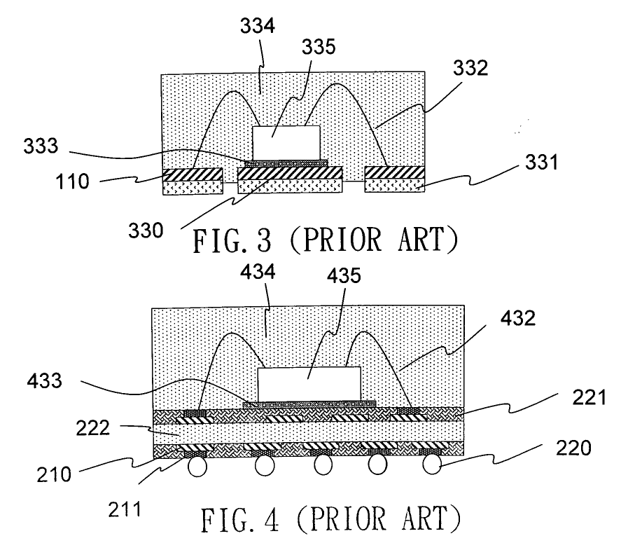

### DETAILED DESCRIPTION OF THE INVENTION

The following uses some embodiments to illustrate the chip package substrate and the chip package structure according to this invention.

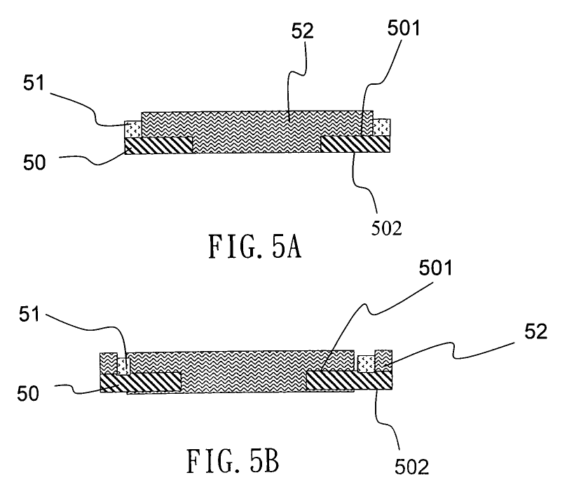

A chip package substrate, shown in FIG. 5A, uses the lead frame substrate as the chip carrier, wherein the lead frame substrate includes a plurality of connection pads 50. An insulation layer 52 is configured on between those connection pads 50 to cover the connection pad 50 but to expose a portion of a first surface 501 of the connection pad 50. In the embodiment, the exposed portion of the first surface 501 is configured on a contact pad 51. A second surface 502, another face of the connection pad 50, is exposed to the insulation layer 52. For a chip package substrate shown in FIG. 5B is different from one in FIG. 5A, the contact pad 51 is moved inward and surrounded by the insulation layer 52.

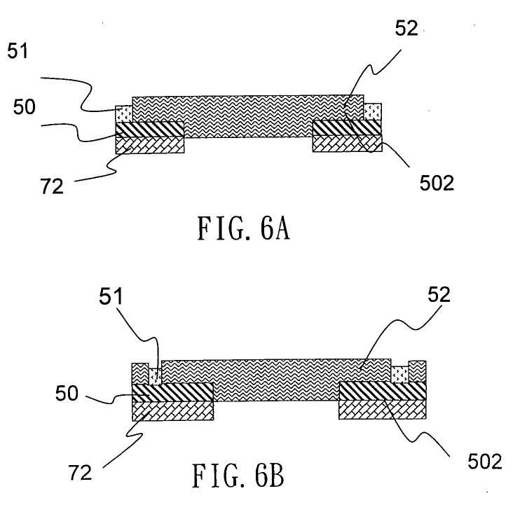

For the chip package substrate shown in FIG. 6A, which is different from one shown in FIG. 5A, a metallic layer 72 is formed on the second surface 502 as the connection point to an external circuit, such as a tin, silver or a nickel-golden layer. Comparing the chip package substrate shown in FIG. 6B with that in FIG. 6A, the contact pad 51 is moved inward more.

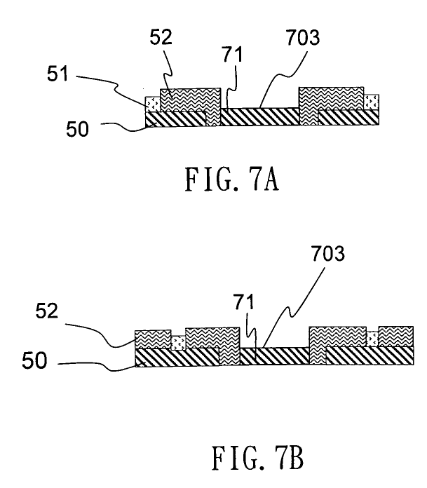

For the chip package substrate shown in FIG. 7A, which is different from the embodiment shown in FIG. 5A, a die pad 71 is formed in the layer of the connection pad 50 between two connection pads 50. The distance between these two connection pads is smaller than the side length of a chip carrier area, and a third surface 703 of the die pad 71, the top face of the chip, is exposed to the insulation layer 52 to form an opening, which may be smaller than the die pad 71 or not. Comparing the embodiment shown in FIG. 7B with that in FIG. 7A, the contact pad 51 is moved inward more.

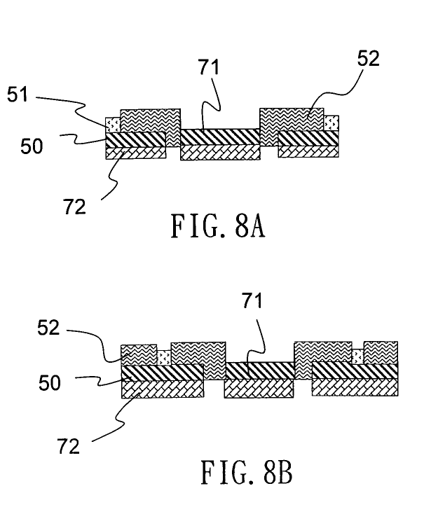

For the chip package substrate shown in FIG. 8A, which is different from the embodiment shown in FIG. 7A, a metallic layer 72 is formed on another face of the connection pad 50, the opposite face to the contact pad 51, as a connection point, which is used to connect to an external circuit. Comparing the chip package substrate shown in FIG. 8B with that in FIG. 8A, the contact pad 51 is moved inward more.

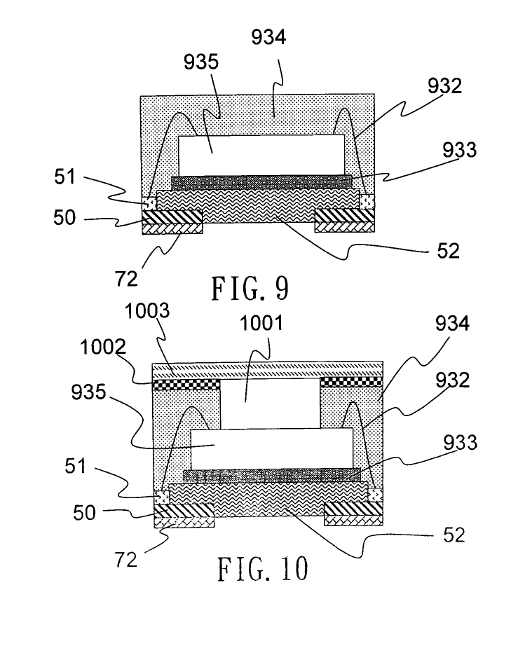

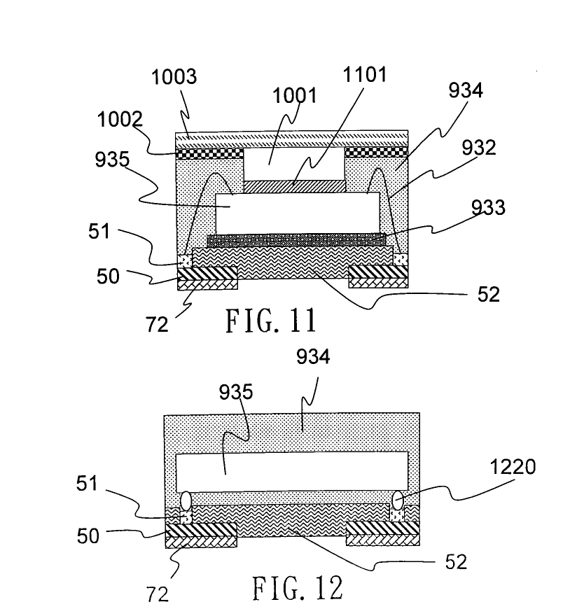

As shown in FIG. 9, the chip package structure uses the chip package substrate, shown in FIG. 6A, as the chip carrier. Except for the structure of the substrate in FIG. 6A, the chip package structure further includes an adhesive layer 933, made of a conductive glue or an insulating glue, which is configured between the insulation layer 52 and a chip 935, a conductive wire 932 electrically connected with the chip 935 and the contact pad 51, and a molding material layer 934 covering components thereof. As shown in FIG. 10, applying this structure to a CMOS sensor chip package structure, except for the structure shown in FIG. 9, the chip package structure further includes an adhesive layer 1002 designed between the molding material layer 934 and a top cap substrate 1003, which may be a glass, a ceramic or a metallic layer. Depending on characteristics of the CMOS sensor chip, an empty space 1001 is configured above the chip, where the empty space 1001 can be formed by removing the molding material layer 934 and the adhesive layer 1002. Accordingly, the chip 935 and the connection pads 50 are overlapped in space, that is, the distance between two connection pads 50 is smaller than the chip carrier area. The embodiment shown in FIG. 11 applies this structure to a pressure sensor chip package structure. Except for the structure shown in FIG. 10, the chip package structure further includes a colloid layer 1101, which is disposed on the chip 935 under the top cap substrate 1003. It may be understood that the carrier can be replaced by a chip package substrate without die pad, shown in FIG. 5A, FIG. 5B or FIG. 6B, or a chip package substrate with die pad, shown in FIG. 7A, FIG. 7B, FIG. 8A or FIG. 8B.

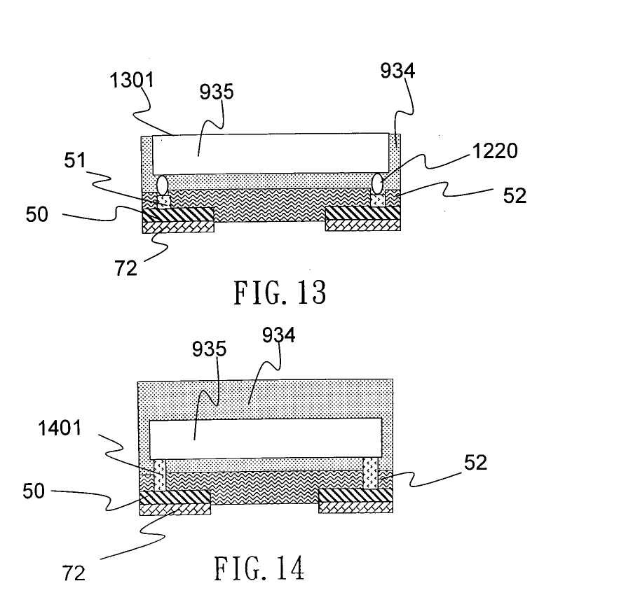

Shown in FIG. 12, the chip package structure uses the chip package substrate, shown in FIG. 6B, as the chip carrier and is applied to the flip chip package technology. In this embodiment, the conductive balls 1220, such as tin balls, are employed to fix the chip 935 and to connect electrically with the contact pads 51, and the molding material layer 934 covers those components thereof subsequently. For the embodiment, shown in FIG. 13, is different from one in FIG. 12, the height of the molding material layer 934 is the same to the chip 935, hence the chip rear surface 1301 is exposed to the molding material layer 934. It may be understood that the carrier can be replaced by a chip package substrate without die pad, shown in FIG. 5A, FIG. 5B or FIG. 6A, or a chip package substrate with die pad, shown in FIG. 7A, FIG. 7B, FIG. 8A or FIG. 8B.

The chip package structure, shown in FIG. 14, uses the chip package substrate, shown in FIG. 6B, as the chip carrier. For this embodiment is different from one shown in FIG. 12, a conductive bump 1401, like a golden bump, replaces the conductive ball 1220 shown in FIG. 12. It may be understood that the carrier can be replaced by a chip package substrate like the embodiments shown in FIG. 12 and FIG. 13.

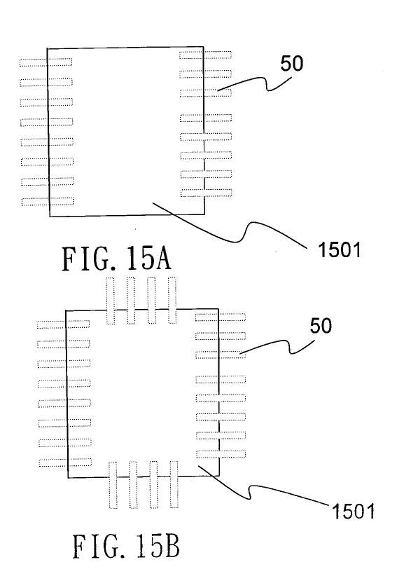

FIG. 15A and FIG. 15B show the top views of the chip package structures according to the embodiments of this invention. As shown in figures, the connection pads 50 are configured around the two or four sides of the chip, and two corresponding connection pads 50 are separated with a distance, which is smaller than the side length of a chip or a chip carrier area 1501. Therefore, the chip and each connection pad 50 are overlapped in space, and, if a die pad is configured between two connection pads 50, the die pad will be smaller than the chip.

Accordingly, this invention provides a chip package substrate, which moves connection pads inward under the chip carrier area to reduce the distance between the chip and the contact pad, thus the chip package structure are shrunk.

Although the present invention has been explained in relation to its preferred embodiment, it is to be understood that other modifications and variation can be made without departing the spirit and scope of the invention as claimed.

What is claimed is:

1. A chip package substrate, comprising:
a plurality of connection pads separated from each other with a distance between two ends of two connection pads, wherein said distance is smaller than one side length of a chip carrier area;
an insulation layer configured on said connection pads but exposing a portion of a first surface of each of said connection pads; and
a plurality of contact pads configured in said insulation layer to cover said exposed portion of said first surface of each of said connection pads

2. A chip package substrate according to claim 1, further comprising a die pad configured between said connection pads, wherein said die pad is smaller than said chip carrier area.

3. A chip package substrate according to claim 2, wherein said insulation layer covers said die pad.

4. A chip package substrate according to claim 2, wherein a portion of a second surface of said die pad is exposed to said insulation layer.

5. A chip package substrate according to claim 4, wherein said portion of said second surface of said die pad is configured on the same face to said contact pad.

6. A chip package substrate according to claim 4, wherein a third surface of said die pad is exposed to said insulation layer, and said third surface is configured on the opposite face to said second surface of said die pad.

7. A chip package substrate according to claim 1, wherein a second surface of each of said connection pads is exposed to said insulation layer, and said second surface of each of said connection pads is configured on the opposite face to said contact pad.

8. A chip package substrate according to claim 7, further comprising a metallic layer configured on said second surface of each of said connection pads.

9. A chip package substrate according to claim 8, further comprising a tin ball configured on said metallic layer.

10. A chip package substrate according to claim 1, wherein said connection pads are metallic leads.

11. A chip package structure comprising:
a plurality of connection pads separated from each other;
an insulation layer configured on said connection pads but exposing a portion of a first surface of each of said connection pads;
a plurality of contact pads configured in said insulation layer to cover said exposed portion of said first surface of each of said connection pads;
a chip installed on said insulation layer, wherein said chip and said connection pads are designed as partially overlapped in space;
a plurality of conductive components electrically connected said chip and each contact pad; and
a molding material layer covering said chip and each conductive component.

12. A chip package structure according to claim 11, further comprising an adhesive layer configured between said chip and said insulation layer.

13. A chip package structure according to claim 11, further comprising a die pad configured between said connection pads, wherein said die pad is smaller than said chip.

14. A chip package structure according to claim 11, wherein said contact pads and said chip are designed as overlapped in space.

15. A chip package structure according to claim 11, wherein said contact pads are configured on both sides of said chip.

16. A chip package structure according to claim 11, wherein a second surface of said chip is exposed to said molding material layer.

17. A chip package structure according to claim 11, further comprising an adhesive layer configured on said molding material layer and a top cap configured on said adhesive layer over said second surface of said chip.

18. A chip package structure according to claim 11, wherein said conductive components are conductive wires.

19. A chip package structure according to claim 11, wherein said conductive components are gold bumps.

20. A chip package structure according to claim 11, wherein said conductive components are tin balls.
